(19) United States
(12) Patent Application Publication
(10) Pub. No.: US 2013/0248987 A1
(43) Pub. Date: Sep. 26, 2013

(54) SEMICONDUCTOR DEVICE AND METHOD FOR MANUFACTURING THE SAME

(71) Applicant: Takashi OKUHATA, Hyogo-ken (JP)

(72) Inventor: Takashi OKUHATA, Hyogo-ken (JP)

(73) Assignee: Kabushiki Kaisha Toshiba, Tokyo (JP)

(21) Appl. No.: 13/601,651

(22) Filed: Aug. 31, 2012

(30) Foreign Application Priority Data
Mar. 23, 2012 (JP) 2012-068432

(51) Int. Cl. H01L 29/78; H01L 21/336

(52) U.S. Cl. 257/330; 438/270; 257/E29.262; 257/E21.41

(57) ABSTRACT

According to one embodiment, a semiconductor device includes a first semiconductor layer of a first conductivity type, a second semiconductor layer of a second conductivity type which is provided on the first semiconductor layer, a third semiconductor layer of the first conductivity type which is selectively provided on a surface of the second semiconductor layer, an insulating film which is provided to cover an inner wall of a trench running into the first semiconductor layer from an upper face of the third semiconductor layer, a field plate electrode which is provided in a lower portion of the trench, a gate electrode which is provided on the field plate electrode via the insulating film, and a fourth semiconductor layer of the second conductivity type which is provided at least in a region direct below the trench, and comes into contact with the insulating film.

### CROSS-REFERENCE TO RELATED APPLICATIONS

This application is based upon and claims the benefit of priority from the prior Japanese Patent Application No. 2012-068432, filed on Mar. 23, 2012; the entire contents of which are incorporated herein by reference.

### FIELD

Embodiments described herein relate generally to a semiconductor device and a method for manufacturing the same.

### BACKGROUND

In a trench type metal-oxide-semiconductor field-effect transistor (MOSFET), as a structure for improving a breakdown voltage while suppressing an on-resistance, there can be thought a field plate structure (hereinafter, referred to as “FP structure”) in which a field plate electrode (hereinafter, referred to as “FP electrode”) is embedded in a trench, and a super junction structure (hereinafter, referred to as “SJ structure”) in which a thick depletion layer is formed while maintaining a high impurity concentration by alternately arranging an n-type pillar and a p-type pillar.

In order to embed the FP electrode, a deep trench is necessary. In general, since a side face of the trench tends to be formed as a taper shape, it is necessary to make an opening width wide if it is intended to make the trench deep. Further, if the trench is made deeper or a field plate insulating film (hereinafter, referred to as “FP insulating film) is made thicker, in order to improve a breakdown voltage, the opening width of the trench becomes wider, and it becomes hard to make fine.

On the other hand, in the case that the SJ structure is formed according to an ion implantation method for reducing a cost, it is necessary to alternately form the p-type pillar and the n-type pillar within a semiconductor board. If it is intended to form each of the pillars deep for making the depletion layer thicker, there is generated a necessity of making an accelerating energy of an ion high, however, the ion having a high energy is scattered within the semiconductor board. As a result, a width of the pillar is expanded, and it becomes hard to make fine.

### BRIEF DESCRIPTION OF THE DRAWINGS

FIG. 1 is a cross sectional view which illustrates a semiconductor device according to a first embodiment;

FIG. 2A is a view illustrating a depletion layer in a semiconductor device of the FP structure;

FIG. 2B is a view illustrating a depletion layer in a semiconductor device of the SJ structure;

FIG. 2C is a view illustrating a depletion layer in the semiconductor device according to the first embodiment;

FIG. 3A is a view illustrating a semiconductor device of a conventional structure;

FIG. 3B is a graph illustrating an electric field intensity in the semiconductor device of the conventional structure, a vertical axis indicates a position in a thickness direction in the semiconductor board, and a horizontal axis indicates the electric field intensity;

FIG. 3C is a view illustrating the semiconductor device according to the first embodiment;

FIG. 3D is a graph illustrating an electric field intensity in the semiconductor device according to the first embodiment, a vertical axis indicates a position in a thickness direction in the semiconductor board, and a horizontal axis indicates an electric field intensity;

FIGS. 4A to 4D, FIGS. 5A to 5D and FIGS. 6A to 6C are process cross sectional views illustrating a method of manufacturing a semiconductor device according to a second embodiment;

### DETAILED DESCRIPTION

In general, according to one embodiment, a semiconductor device includes a first semiconductor layer of a first conductivity type, a second semiconductor layer of a second conductivity type which is provided on the first semiconductor layer, a third semiconductor layer of the first conductivity type which is selectively provided on a surface of the second semiconductor layer, an insulating film which is provided to cover an inner wall of a trench running into the first semiconductor layer from an upper face of the third semiconductor layer, a field plate electrode which is provided in a lower portion of the trench, a gate electrode which is provided on the field plate electrode via the insulating film, and a fourth semiconductor layer of the second conductivity type which is provided at least in a region direct below the trench, and comes into contact with the insulating film.

According to another embodiment, a method is disclosed for manufacturing a semiconductor device. The method can form a plurality of trenches extending in one direction on an upper face of a semiconductor board of a first conductivity type. The method can form a fourth semiconductor layer of a second conductivity type in such a manner as to expose to an inner face of the trench, at least in a region direct below the trench in the semiconductor board, and form a second semiconductor layer of a second conductivity type in an upper layer portion in the semiconductor board, by implanting an impurity from the above to the semiconductor board. The method can form a field plate insulating film on the inner face of the trench. The method can form a field plate electrode by embedding a conductive material in a lower portion of the trench. The method can form a gate insulating film on an upper face of the field plate electrode and on the inner face of the trench. The method can form a gate electrode in such a manner that a lower end becomes lower than a lower face of the second semiconductor layer by embedding a conductive material on the field plate electrode within the trench. The method can form a third conductive layer of the first conductivity type in a portion which is an upper layer portion of the second conductive layer, comes into contact with the gate insulating film, and becomes lower in its lower face than an upper end of the gate electrode, by selectively implanting the impurity from the above to the second semiconductor layer. The method can forming a first conductive film in such a manner as to come into contact with an upper face of the semiconductor board. The method can form a second conductive film in such a manner as to come into contact with a lower face of the semiconductor board.

Various embodiments will be described hereinafter with reference to the accompanying drawings.

### First Embodiment

A description will be given below of embodiments of the invention with reference to the accompanying drawings.

First of all, a description will be given of a first embodiment.

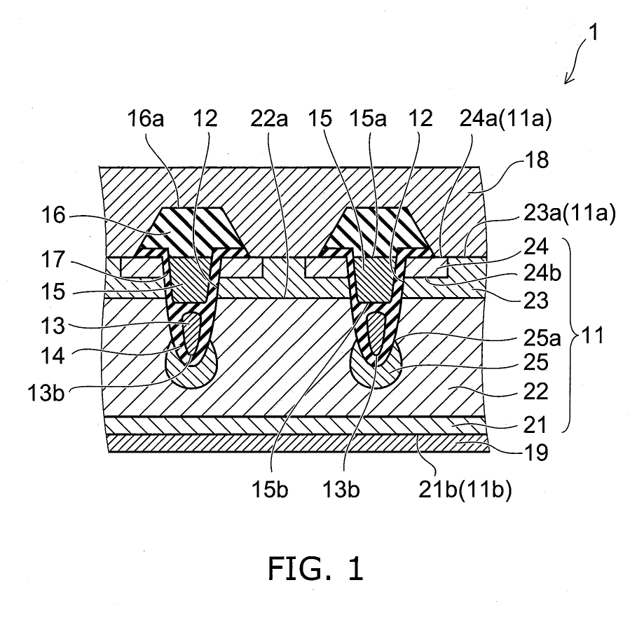

FIG. 1 is a cross sectional view which illustrates a semiconductor device according to the first embodiment.

As shown in FIG. 1, a semiconductor device 1 according to the embodiment has a drain layer 21. An impurity, for example, a phosphorous to be a donor is included in the drain layer 21. A conductivity type of the drain layer 21 is an n-type. A drift layer 22 is provided on the drain layer 21 so as to be in contact with the drain layer 21. An impurity, for example, a phosphorous to be a donor is included in the drift layer 22. A conductivity type of the drift layer 22 is an n-type. The drain layer 21 and the drift layer 22 are n-type semiconductor layers. In this case, an effective impurity concentration of the drift layer 22 is lower than an effective impurity concentration of the drain layer 21.

In this case, “effective impurity concentration” in the specification means a concentration of the impurity which contributes to a conduction of the semiconductor material, for example, in the case that both the impurity to be the donor and the impurity to be an acceptor are included in the semiconductor material, it means a concentration of a content except a compensating amount of the donor and the acceptor.

A base layer 23 is provided on the drift layer 22 so as to be in contact with the drift layer 22. The impurity, for example, a boron to be the acceptor is included in the base layer 23. A conductivity type of the base layer 23 is the p-type. A source layer 24 is selectively provided on a surface of the base layer 23. The impurity, for example, a phosphorous to be the donor is included in the source layer 24. A conductivity type of the source layer 24 is the n-type. A position of an upper face of the base layer 23 and a position of an upper face of the source layer 24 are set to the same height.

A plurality of trenches 12 which runs into the drift layer 22 from the upper face of the source layer 24 are provided on the upper face of the source layer 24. The trench 12 is formed in such a manner as to extend in one direction within a face which is parallel to the upper face of the source layer 24. For example, the one direction is a direction which is vertical to the drawing. The source layer 24 extends in one direction along the trench 12. Further, the source layer 24 is expanded at a predetermined width in another direction which is orthogonal to the one direction within the face which is parallel to the upper face of the source layer 24, from the trench 12. For example, the another direction is a right direction of the drawing.

In the specification, the direction in which the trench 12 extends is called as “trench extending direction”. Further, the direction which is orthogonal to the trench extending direction within the face which is parallel to the upper face of the source layer 24 is called as “trench arranging direction”.

The base layer 23 is interposed between the source layers 24 which are arranged between the adjacent trenches 12.

For example, an FP insulating film 14 and a gate insulating film 17 which are configured by a silicon oxide film are provided in such a manner as to cover an inner wall of the trench 12. The FP insulating film 14 is arranged in a lower portion of the trench 12, and the gate insulating film 17 is arranged in an upper portion of the trench 12. An FP electrode 13 is provided in a lower portion of the trench 12. The FP electrode 13 is formed by a conductive material, for example, by a polysilicon (polycrystalline silicon) to which an impurity is added. An upper end of the FP electrode 13 is positioned below the upper face of the drift layer 22. The FP insulating layer 14 is arranged between the FP electrode 13 and the drift layer 22.

A gate electrode 15 is provided on the FP electrode 13. The gate electrode 15 is formed by a conductive material, for example, the polysilicon to which the impurity is added. A lower end 15b of the gate electrode 15 is positioned below the upper face of the drift layer 22. An upper end 15a of the gate electrode 15 is positioned above the lower face of the source layer 24. The gate insulating film 17 is arranged between the gate electrode 15 and the drift layer 22, the base layer 23, and the source layer 24. Further, the gate insulating film 17 is arranged between the gate electrode 15 and the FP electrode 13. Accordingly, the gate electrode 15 is arranged on the FP electrode 13 via the gate insulating film 17.

A p-type semiconductor layer 25 is provided in a region directly below the trench 12. The region directly below a certain thing is a region just under it. The region direct below the trench 12 means a region which covers a direction of the drain layer 21 in the directions which are vertical to the upper face of the source layer 24, as seen from the trench 12. The impurity, for example, the boron to be the acceptor is included in the p-type semiconductor layer 25. A conductivity type of the p-type semiconductor layer 25 is the p-type. The p-type semiconductor layer 25 is in contact with the FP insulating film 14. Further, an upper end 25a of the p-type semiconductor layer 25 is positioned above the lower end 13b of the FP electrode 13. As a result, the p-type semiconductor layer 25 is arranged in a side direction of the lower portion of the FP electrode 13.

The same kind of dopant impurity is included in the p-type semiconductor layer 25 and the base layer 23. Further, it is included at the same dose amount. The semiconductor board 11 is configured by the source layer 24, the base layer 23, the drift layer 22, the drain layer 21 and the p-type semiconductor layer 25.

The insulating film 16 made of an insulating material, for example, a silicon oxide is provided on the gate electrode 15. An upper face 16a of the insulating film 16 is positioned above the upper face 11a of the semiconductor board 11. A portion on the upper face 11a of the semiconductor board 11 in the insulating film 16 protrudes in both side face directions of the trench 12. The insulating film 16 covers a portion in a side which is closer to the trench 12 in the upper face 24a of the source layer 24. A portion in a side which is farther from the trench 12 in the upper face 24a of the source layer 24 is not covered by the insulating film 16. The gate insulating film 17 is arranged between the insulating film 16 and the source layer 24.

The upper face 24a of the source layer 24 and the upper face 23a of the base layer 23 are in contact with the source electrode 18. The lower face 21b of the drain layer 21 is in contact with the drain electrode 19. The p-type semiconductor layer 25 is floating, that is, in an independent electric potential without being electrically connected to the source electrode 18, the drain electrode 19, the gate electrode and the FP electrode. Further, the p-type semiconductor layer 25 may be connected to the source electrode 18 and be set to the same electric potential as the source electrode 18. In the semiconductor device 1, the configuration shown in FIG. 1 is repeatedly arranged. FIG. 1 shows two basic units.

Next, a description will be given of a motion of the semiconductor device according to the embodiment.

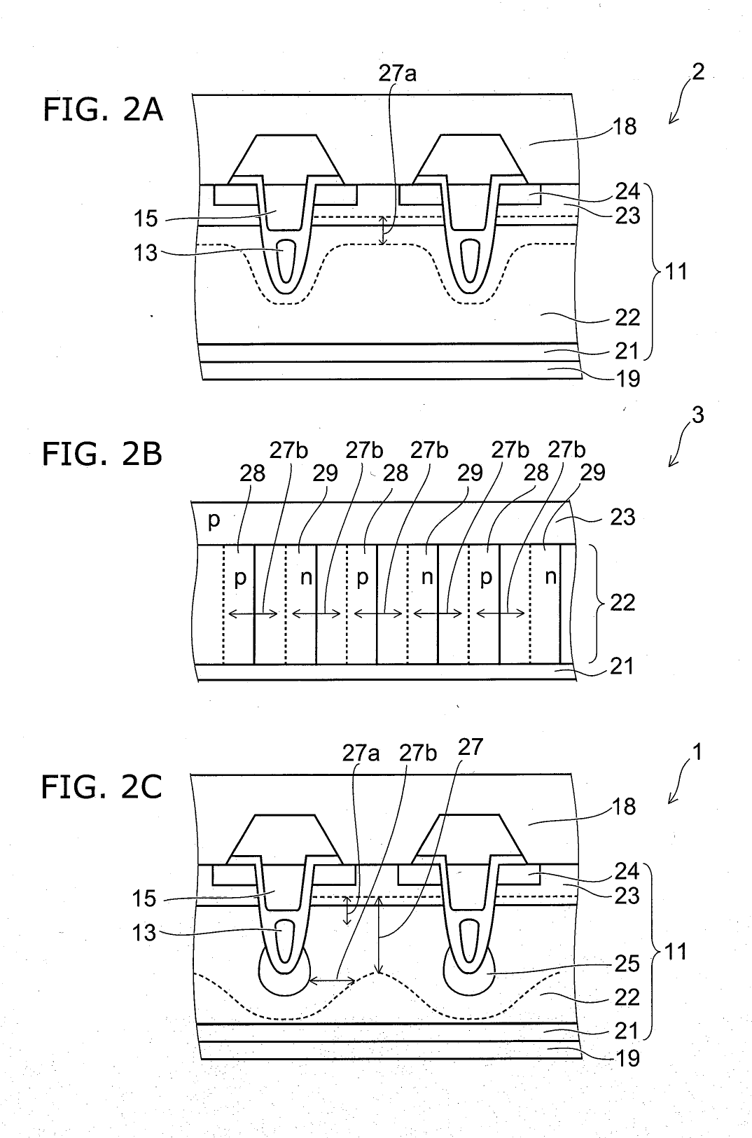

FIG. 2A is a view illustrating a depletion layer in a semiconductor device of the FP structure, FIG. 2B is a view illustrating a depletion layer in a semiconductor device of the SJ structure, and FIG. 2C is a view illustrating a depletion layer in the semiconductor device according to the first embodiment.

As shown in FIG. 2A, in a semiconductor device 2 in which only the FP structure is formed, if an electric voltage is applied between the source electrode 18 and the drain electrode 19, a depletion layer 27a is formed by setting an interface between the drift layer 22 and the base layer 23 as a generating face. Further, for example, if the same electric potential as the source electrode 18 is applied to the FP electrode 13, an electric field which the FP electrode 13 forms absorbs an electric field concentration between the gate electrode 15 and the drain electrode 19.

On the other hand, as shown in FIG. 2B, in a semiconductor device 3 in which only the SJ structure that a plurality of p-type pillars 28 and n-type pillars 29 extending in one direction within a face which is parallel to the upper face of the drain layer 21 are alternately arranged in another direction which is orthogonal to the one diction is formed on the drain layer 21, if an electric voltage is applied between the source electrode 18 (not illustrated) and the drain electrode 19 (not illustrated), a depletion layer 27b is generated from an interface between the p-type pillar 28 and the n-type pillar 29 in the drift layer 22, and extends in the another direction and an inverse direction to the another direction. Further, the depletion layer 27b is expanded over a whole of the drift layer 22.

As shown in FIG. 2C, in the semiconductor device 1, if a power supply potential of a negative electrode is applied to the source electrode 18, and a power supply potential of a positive electrode is applied to the drain electrode 19, the action of the FP structure and the action of the SJ structure mentioned above are superposed, and a depletion layer 27 configured by the depletion layers 27a and 27b is formed within the drift layer 22 and the base layer 23.

The depletion layer 27a is formed by setting the interface between the drift layer 22 and the base layer 23 as a generating face in the same manner as the case of the semiconductor device 2 of the FP structure. Further, an electric field which the FP electrode 13 forms promotes an extension in a vertical direction of the depletion layer 27a.

The depletion layer 27b is formed by setting the interface between the drift layer 22 and the p-type semiconductor layer as a generating face, in the same manner as the semiconductor device 3 of the SJ structure. Further, the depletion layer 27b extends in a trench arranging direction. The electric potential of the p-type semiconductor layer 25 is set to a floating, that is, an independent electric potential which is not connected anywhere. As a result, it is possible to extend the depletion layer 27b in the trench arranging direction. Further, the p-type semiconductor layer 25 may be connected to the source electrode 18 so as to set the electric potential of the p-type semiconductor layer 25 to the same electric potential as the source electrode 18.

In the embodiment, if an on action is achieved by applying a higher electric potential than a threshold value to the gate electrode 15, an inversion layer is formed in the vicinity of the gate insulating film 17 in the base layer 23, and an electric current flows from the drain electrode 19 via the drain layer 21, the drift layer 22, the base layer 23 and the source layer 24. On the other hand, if an off action is achieved by applying an electric potential which is lower than a threshold value to the gate electrode 15, the inversion layer disappears and the electric current is shut off.

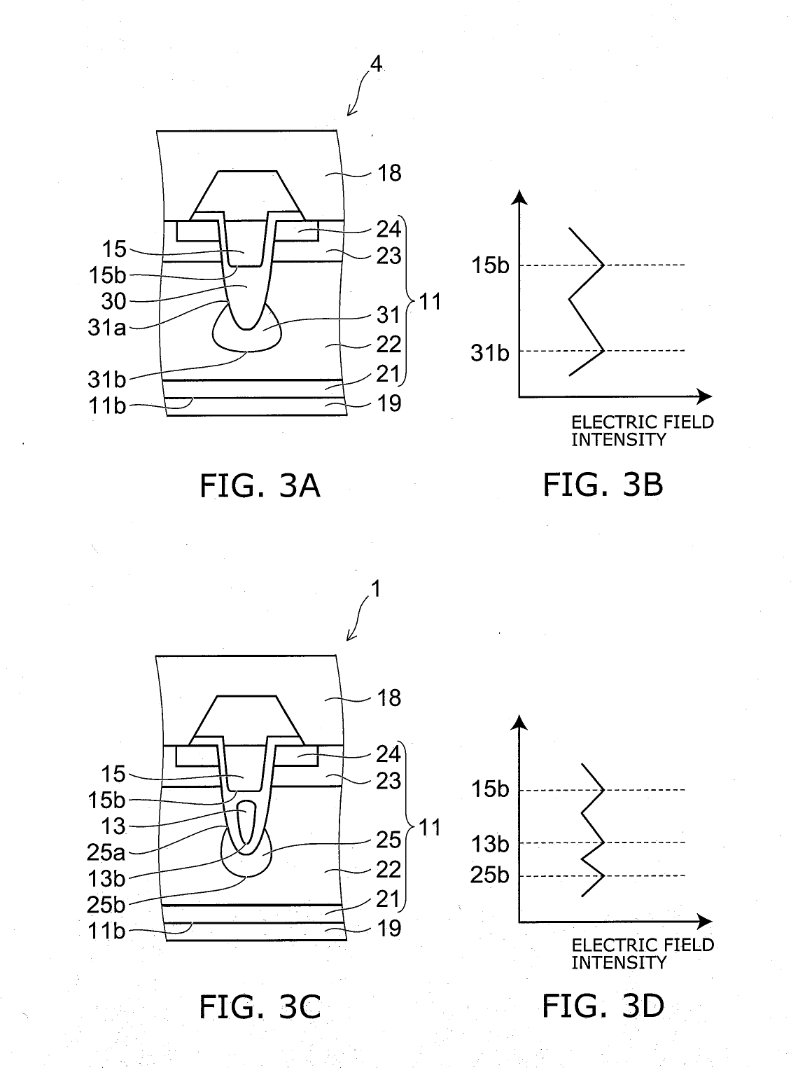

FIG. 3A is a view illustrating a semiconductor device of a conventional structure, FIG. 3B is a graph illustrating an electric field intensity in the semiconductor device of the conventional structure, a vertical axis indicates a position in a thickness direction in the semiconductor board, and a horizontal axis indicates the electric field intensity. FIG. 3C is a view illustrating the semiconductor device according to the first embodiment, FIG. 3D is a graph illustrating an electric field intensity in the semiconductor device according to the first embodiment, a vertical axis indicates a position in a thickness direction in the semiconductor board, and a horizontal axis indicates an electric field intensity.

As shown in FIGS. 3A and 3B, in a semiconductor device 4 of the conventional structure, the semiconductor board 11 is provided, and a plurality of trenches 12 are formed on the upper face 11a of the semiconductor board 11. An insulating film 30, for example, a silicon oxide film is embedded in the lower portion of the trench 12. The gate electrode 15 is provided on the insulating film 30 in the upper portion within the trench 12. The gate insulating film 17 is provided between the gate electrode 15 and the semiconductor board 11.

The semiconductor board 11 is provided with the drain layer 21, the drift layer 22, the base layer 23, the source layer 24 and an impurity layer 31. The impurity layer 31 is arranged at least in a region direct below the trench 21 in the drift layer 22. The impurity, for example, the boron to be the acceptor is included in the impurity layer 31. A conductivity type of the impurity layer 31 is the p-type. The impurity layer 31 comes into contact with the silicon oxide film 30. Further, an upper end 31a of the impurity layer 31 is positioned below the lower end 15b of the gate electrode 15. The impurity layer 31 is arranged in a side direction of a lower portion of the insulating film 30. The other configurations than the above in the semiconductor device 4 of the conventional structure are the same as the first embodiment mentioned above.

In the semiconductor device 4 of the conventional structure, if the electric voltage is applied between the source electrode 18 and the drain electrode 19, the electric field intensity in the semiconductor board 11 becomes higher in a lower end 15b of the gate electrode 15 and a lower end 31b of the impurity layer 31 in a thickness direction. Accordingly, in the semiconductor device 4 of the conventional structure, the electric field is concentrated at two positions including the lower end 15b of the gate electrode 15 and the lower end 31b of the impurity layer 31.

On the other hand, as shown in FIGS. 3C and 3D, in the semiconductor device 1 according to the embodiment, if the electric voltage is applied between the source electrode 18 and the drain electrode 19, the electric field intensity in the semiconductor board 11 becomes higher in the lower end 15b of the gate electrode 15, the lower end 13b of the FP electrode 13 and a lower end 25b of the p-type semiconductor layer 25 in the thickness direction. Accordingly, in the semiconductor device 1 of the embodiment, the electric field is concentrated at three positions including the lower end 15b of the gate electrode 15, the lower end 13b of the FP electrode 13 and the lower end 25b of the p-type semiconductor layer 25.

Next, a description will be given of an effect in the embodiment.

In the semiconductor device 1 according to the embodiment, the FP structure is formed in the upper portion of the semiconductor board 11. Accordingly, the depletion layer 27a is formed by setting the interface between the drift layer 22 and the base layer 23 as a generating face. Further, on the basis of the electric field which the FP electrode 13 forms, it is possible to absorb the electric field concentration within the semiconductor board 11 and extend the depletion layer 27a in the vertical direction.

On the other hand, the SJ structure is formed below the FP structure. Accordingly, the depletion layer 27b is formed by setting the interface between the drift layer 22 and the p-type semiconductor layer 25 as a generating face. Further, the formed depletion layer 27b is expanded in the trench arranging direction. As mentioned above, by forming the FP structure and the SJ structure, it is possible to improve a breakdown voltage of the semiconductor device 1.

Further, since the semiconductor device 1 is provided with both the FP structure and the SJ structure, it is possible to increase the generating face of the depletion layer in comparison with the provision of only one of the structures. Accordingly, it is possible to improve a breakdown voltage of the semiconductor device 1.

Further, in order to improve the breakdown voltage only by the FP structure, the deep trench 12 is necessary. In this case, an opening width of the trench 12 is expanded, and it becomes hard to make fine. On the other hand, in order to improve the breakdown voltage only by the SJ structure, it is necessary to form the p-type pillar 28 and the n-type pillar 29 deep. In this case, an ion having a high energy is scattered within the semiconductor board 11. As a result, the widths of the p-type pillar 28 and the n-type pillar 29 are expanded, and it becomes hard to make fine.

However, by forming a structure in which the FP structure and the SJ structure are arranged up and down, such as the semiconductor device 1, it is neither necessary to form the deep trench 12, nor necessary to form the p-type pillar 28 and the n-type pillar 29 deep, and it is possible to improve the breakdown voltage of the semiconductor device 1. Therefore, it is possible to make the semiconductor device 1 fine.

Further, the semiconductor layer 25 is formed in the region direct below the trench 12, and is not provided on a route of the on electric current of the semiconductor device 1. As a result, the on electric current is not blocked by the p-type semiconductor layer 25, and it is possible to absorb an on-resistance of the semiconductor device 1.

Further, the upper end 25a of the p-type semiconductor layer 25 is positioned above the lower end 13b of the FP electrode 13. As a result, the lower end 13b of the FP electrode 13 in which the electric field concentration tends to be generated is covered by the p-type semiconductor layer 25 in which the electric field is constant. Accordingly, the electric field concentration is absorbed. Further, since the p-type semiconductor layer 25 is arranged in a side direction of the lower portion of the FP electrode 13, it is possible to expand the depletion layer 27b in the vertical direction. Therefore, it is possible to improve the breakdown voltage of the semiconductor device 1.

Further, comparing the semiconductor device 1 according to the embodiment with the semiconductor device 4 of the conventional structure, the number of the position at which the electric field is concentrated is two positions including the lower end 15b of the gate electrode 15 and the lower end 31b of the impurity layer 31, in the semiconductor device 4 of the conventional structure. On the contrary, in the semiconductor device 1 according to the embodiment, it is three positions including the lower end 15b of the gate electrode 15, the lower end 13b of the FP electrode 13 and the lower end 25b of the p-type semiconductor layer 25. Accordingly, it is possible to disperse the position at which the electric field is concentrated. Therefore, in the semiconductor device 4 of the conventional structure, there is generated a necessity of dispersing the electric field in the lower end 31b of the impurity layer 31 by expanding the impurity layer 31 in the trench arranging direction. On the contrary, in the semiconductor device 1 according to the embodiment, it is possible to form while suppressing the expansion in the trench arranging direction of the p-type semiconductor layer 25. As a result, it is possible to make the semiconductor device 1 fine.

It is possible to extend the depletion layer 27b by floating the p-type semiconductor layer 25. Further, it is possible to control a magnitude of the depletion layer 27b by making the p-type semiconductor layer 25 at, the same electric potential as the electric potential of the source electrode 18.

### Second Embodiment

Next, a description will be given of a second embodiment.

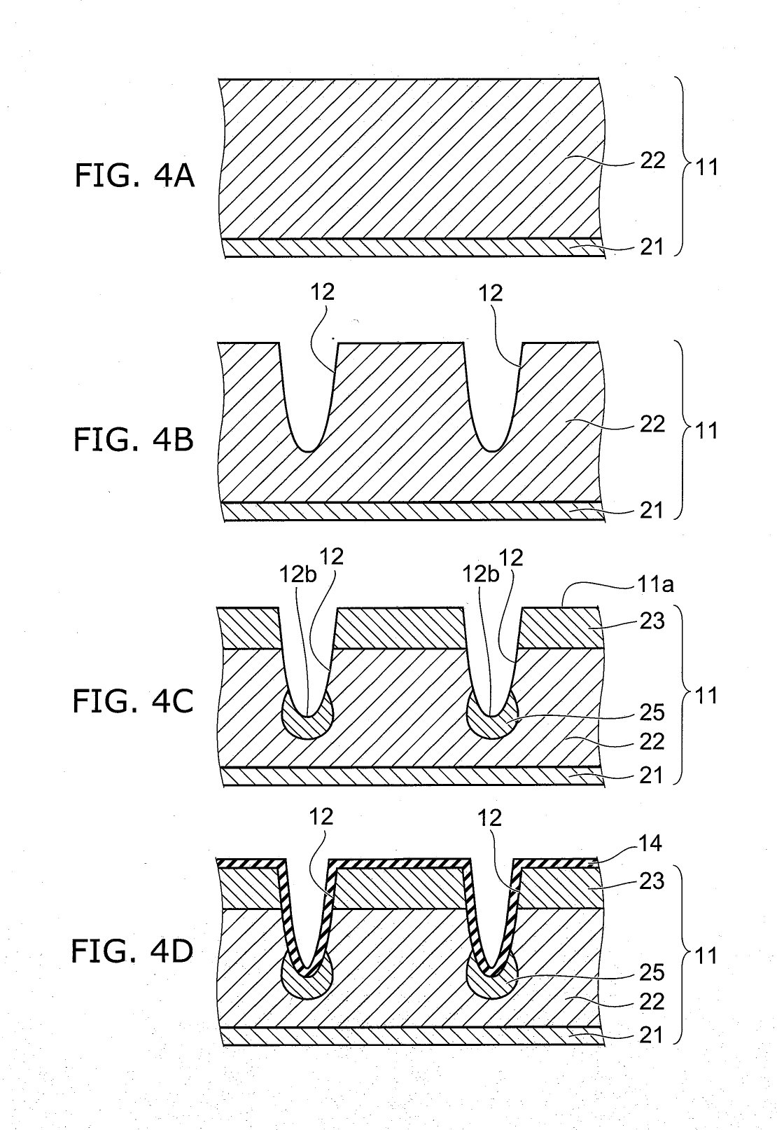

FIGS. 4A to 4D, FIGS. 5A to 5D and FIGS. 6A to 6C are process cross sectional views illustrating a method of manufacturing a semiconductor device according to the second embodiment.

The embodiment is an embodiment about the method of manufacturing the semiconductor device 1 according to the first embodiment mentioned above.

First of all, as shown in FIG. 4A, the semiconductor board 11 is prepared. The semiconductor board 11 is configured such that the drift layer 22 is formed on the drain layer 21. The conductivity types of the drain layer 21 and the drift layer 22 are the n-type. In this case, an effective impurity concentration of the drift layer 22 is lower than an effective impurity concentration of the drain layer 21.

Next, as shown in FIG. 4B, by applying, for example, an anisotropic etching such as a reactive ion etching (RIE) or the like to the semiconductor board 11, a plurality of trenches 12 extending in one direction are formed at equal intervals on the upper face 11a of the semiconductor board 11. At this time, the trench 12 is formed narrower toward a below portion.

Further, as shown in FIG. 4C, the impurity, for example, the boron to be the acceptor is ion-implanted from the above to the semiconductor board 11. As a result, the conductivity type of an upper layer portion than the lower end 12b of the trench 12 in the semiconductor board 11 is changed to the p-type from the n-type. As a result, the base layer 23 is formed in the upper layer of the semiconductor board 11. Further, the conductivity type of at least the portion in the region direct below the trench 12 in the semiconductor board 11 is changed to the p-type from the n-type. As a result, at least in the region direct below the trench 12, the p-type semiconductor layer 25 is formed in such a manner as to expose to the inner face which includes the side face of the trench 12.

Next, as shown in FIG. 4D, the FP insulating film 14 is formed on the semiconductor board 11 which includes the inner face of the trench 12, for example, by carrying out a thermal oxidation treatment.

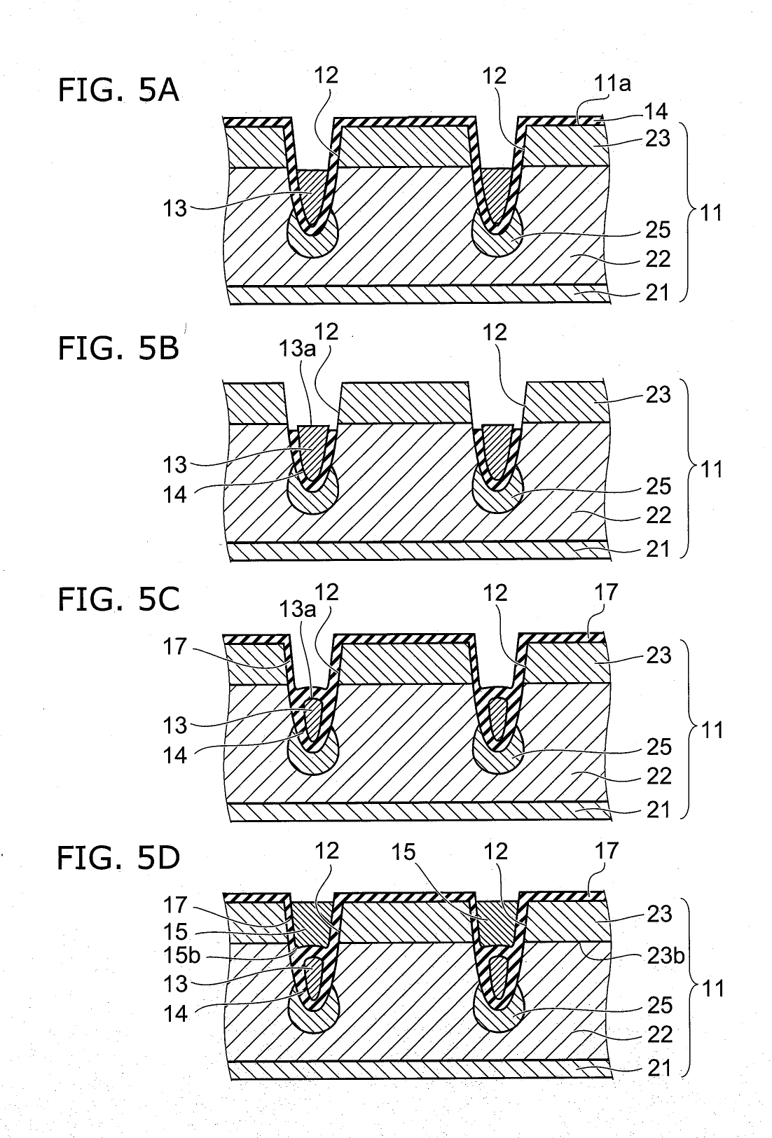

Next, as shown in FIG. 5A, the impurity, for example, the polysilicon including the phosphorous is deposited on a whole face of the semiconductor board 11, for example, according to a chemical vapor deposition (CVD) method. Next, a portion which is deposited on the upper face 11a of the semiconductor board 11 and a portion which is embedded in the upper portion within the trench 12 in the deposited polysilicon are removed by carrying out an etching back. As a result, the polysilicon is left in the lower portion within the trench 12, and the FP electrode 13 is formed.

Next, as shown in FIG. 5B, the portion which is positioned on the upper face 13a of the FP electrode 13 in the FP insulating film 14 is removed by carrying out the etching. As a result, the portion which is below the upper face 13a of the FP electrode 13 in the FP insulating film 14 is left.

Next, as shown in FIG. 5C, for example, the gate insulating film 17 is formed on the upper face 13a of the FP electrode 13 on the inner face of the trench 12, on the upper face 13a of the FP electrode 13 and on the upper face 11a of the semiconductor board 11 by carrying out the thermal oxidation treatment.

Next, as shown in FIG. 5D, the impurity, for example, the polysilicon including the phosphorous is deposited on a whole face of the semiconductor board 11, for example, according to the CVD method. Next, the portion which is deposited on the upper face 11a of the semiconductor board 1 in the deposited polysilicon is removed by carrying out the etching back. As a result, the polysilicon is left in the inner portion of the trench 12, and the gate electrode 15 is formed.

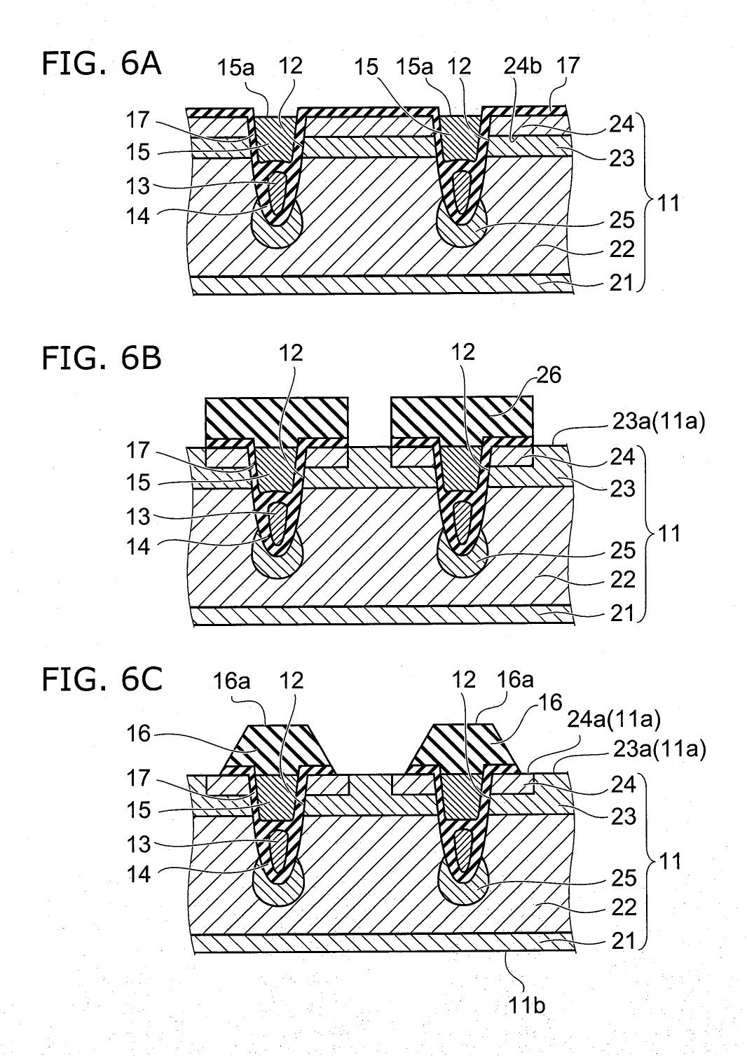

Further, as shown in FIG. 6A, the impurity, for example, the phosphorous to be the donor is ion-implanted from the above to the base layer 23. As a result, the conductivity type of the upper layer portion in the base layer 23 is changed to the n-type from the p-type to form the source layer 24. The lower face 24b of the source layer 24 is positioned below the upper end 15a of the gate electrode 15.

Next, as shown in FIG. 6B, the silicon oxide is deposited on a whole face, for example, according to the CVD method. Further, for example, according to the RIE, the insulating film 26 is formed by selectively removing the portion between the trenches 12 in the silicon oxide, and leaving the portion on the trench 12 and the portion which protrudes to both side faces from the portion on the trench 12. At this time, the portion which is not covered by the insulating film 26 in the gate insulating film 17 is removed.

Thereafter, the impurity, for example, the boron to be the acceptor is ion-implanted from the above to the source layer 24 with the insulating film 26 as a mask. As a result, the conductivity type of the portion which is not covered by the insulating film 26 in the source layer 24 is changed to the p-type from the n-type, and is integrated with the base layer 23 which is positioned below the lower face 24b of the source layer 24. Accordingly, the base layer 23 is formed between the region direct below the source layer 24 and the region direct below the insulating film 26 on the drift layer 22. As a result, the upper face 23a of the base layer 23 is exposed between the just below regions of the insulating film 26. On the other hand, the source layer 24 is positioned in the region direct below the insulating film 26 on the base layer 23. Further, the source layer 24 comes into contact with the insulating film in the upper portion of the trench 12.

Next, as shown in FIG. 6C, the insulating film 26 (refer to FIG. 6B) is etched, and the portions in both sides of the insulating film 26 (refer to FIG. 6B) are removed. As a result, the side face of the insulating film 26 (refer to FIG. 6A) goes back to the trench 12 side, and the insulating film 16 is formed. Further, a portion in an opposite side to the trench 12 in the upper face 24a of the source layer 24 is exposed.

Thereafter, as shown in FIG. 1, the source electrode 18 is formed in such a manner as to cover the upper face 11a of the semiconductor board 11. The source electrode 18 comes into contact with the upper face 23a of the base layer 23 and the upper face 24a of the source layer 24, and covers the insulating film 16. On the other hand, the drain electrode 19 is formed on the lower face 11b of the semiconductor board 11.

As a result, as shown in FIG. 1, the semiconductor device 1 is manufactured.

Next, a description will be given of an effect of the embodiment.

In the embodiment, the p-type semiconductor layer 25 is formed at least in the region direct below the trench 12 by using the other portions than the trench 12 in the semiconductor board 11 as a mask. Accordingly, the p-type semiconductor layer 25 can be formed in the region direct below the trench 12 according to a self-aligning manner not depending on a lithography.

Further, since the p-type semiconductor layer 25 is formed at the same time as the ion implantation at a time of forming the base layer 23, it is not necessary to newly provide a forming process of the p-type semiconductor layer 25, and it is possible to shorten a manufacturing process.

Further, since the p-type semiconductor layer 25 is formed in the region direct below the trench 12, it is possible to reduce an influence by which the implanted ion is scattered by the semiconductor board 11. Therefore, it is possible to suppress an expansion of the width of the p-type semiconductor layer 25, and it is possible to make the semiconductor device 1 fine.

In accordance with the embodiments described above, it is possible to provide the semiconductor device which can form fine, and the method of manufacturing the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor layer of a first conductivity type;
a second semiconductor layer of a second conductivity type which is provided on the first semiconductor layer;
a third semiconductor layer of the first conductivity type which is selectively provided on a surface of the second semiconductor layer;
an insulating film which is provided to cover an inner wall of a trench running into the first semiconductor layer from an upper face of the third semiconductor layer;
a field plate electrode which is provided in a lower portion of the trench;
a gate electrode which is provided on the field plate electrode via the insulating film; and
a fourth semiconductor layer of the second conductivity type which is provided at least in a region direct below the trench, and comes into contact with the insulating film.

2. The device according to claim 1, wherein the fourth semiconductor layer is configured such that an upper end is positioned above a lower end of the field plate electrode.

3. The device according to claim 1, wherein a same kind of dopant impurity is included in the second semiconductor layer and the fourth semiconductor layer.

4. The device according to claim 1, wherein the fourth semiconductor layer is a floating.

5. The device according to claim 1, further comprising:
a first electrode which is connected to upper faces of the second semiconductor layer and the third semiconductor layer; and
a second electrode which is connected to a lower face of the first semiconductor layer,
wherein the fourth semiconductor layer is at a same electric potential as the first electrode.

6. The device according to claim 1, wherein the first semiconductor layer includes a fifth semiconductor layer of the first conductivity type, and a sixth semiconductor layer of the first conductivity type which is provided on the fifth semiconductor layer and has an effective impurity concentration lower than an effective impurity concentration of the fifth semiconductor layer.

7. The device according to claim 1, wherein the third semiconductor layer extends in one direction along the trench.

8. The device according to claim 1, wherein a plurality of the trenches are provided at plural number, and the second semiconductor layer is interposed between the third semiconductor layers which are arranged between the adjacent trenches.

9. The device according to claim 1, further comprising an insulating film which is provided on the gate electrode and protrudes to both side directions of the trench.

10. A method of manufacturing a semiconductor device comprising:
forming a plurality of trenches extending in one direction on an upper face of a semiconductor board of a first conductivity type;
forming a fourth semiconductor layer of a second conductivity type in such a manner as to expose to an inner face of the trench, at least in a region direct below the trench in the semiconductor board, and forming a second semiconductor layer of a second conductivity type in an upper layer portion in the semiconductor board, by implanting an impurity from the above to the semiconductor board;
forming a field plate insulating film on the inner face of the trench;
forming a field plate electrode by embedding a conductive material in a lower portion of the trench;
forming a gate insulating film on an upper face of the field plate electrode and on the inner face of the trench;
forming a gate electrode in such a manner that a lower end becomes lower than a lower face of the second semiconductor layer by embedding a conductive material on the field plate electrode within the trench;
forming a third conductive layer of the first conductivity type in a portion which is an upper layer portion of the second conductive layer, comes into contact with the gate insulating film, and becomes lower in its lower face than an upper end of the gate electrode, by selectively implanting the impurity from the above to the second semiconductor layer;
forming a first conductive film in such a manner as to come into contact with an upper face of the semiconductor board; and
forming a second conductive film in such a manner as to come into contact with a lower face of the semiconductor board.

11. The method according to claim 10, wherein the trench is formed narrower toward a lower portion in the forming of the trench,
the fourth semiconductor layer is formed in a portion which is exposed to a side face of the trench in the forming of the second semiconductor layer, and
a lower end of the field plate electrode is formed in such a manner as to become lower than an upper end of the fourth semiconductor layer in the forming of the filed plate electrode.

12. The method according to claim 10, wherein the semiconductor board is configured such as to include a fifth semiconductor layer of the first conductivity type, and a sixth semiconductor layer of the first conductivity type which is provided on the fifth semiconductor layer, and has an effective impurity concentration lower than an effective impurity concentration of the fifth semiconductor layer.

13. The method according to claim 10, wherein the forming of the field plate electrode includes removing a portion which is positioned on the upper face of the field plate electrode in the field plate insulating film.

14. The method according to claim 10, wherein the forming of the gate insulating film forms the gate insulating film on the upper face of the semiconductor board.

15. The method according to claim 10, further comprising forming an insulating film which includes a portion on the trench and a portion protruding to both side faces from the portion on the trench, after the forming of the third semiconductor layer.

16. The method according to claim 15, further comprising removing a portion which is not covered by the insulating film in the gate insulating film by using the insulating film as a mask.

17. The method according to claim 15, further comprising selectively implanting an impurity to the third semiconductor layer by using the insulating film as a mask, and changing the conductivity type of the portion which is not covered by the insulating film in the third semiconductor layer.

18. The method according to claim 15, further comprising removing a portion in both sides of the insulating film.

19. The method according to claim 10, wherein the forming of the first conductive film forms the first conductive film in such a manner as to come into contact with the upper face of the second semiconductor layer and the upper face of the third semiconductor layer.
